(19) United States
(12) Patent Application Publication
(10) Pub. No.: US 2006/0060919 A1
(43) Pub. Date: Mar. 23, 2006

(54) LOW TEMPERATURE POLYSILICON THIN FILM TRANSISTOR AND METHOD OF FABRICATING LIGHTLY DOPED DRAIN THEREOF

(76) Inventor: Hsi-Ming Chang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,473

(22) Filed: Sep. 21, 2004

(51) Int. Cl. H01L 29/06; H01L 21/84; H01L 29/04

(52) U.S. Cl. 257/347; 438/149; 257/59; 257/72; 438/151

(57) ABSTRACT

A method of fabricating a lightly doped drain region of a low temperature polysilicon thin film transistor is provided. First, a polysilicon layer is formed over a substrate, and then a gate insulation layer is formed over the polysilicon layer. A gate buffer layer and a gate are formed over the gate insulation layer, wherein the gate is formed on the gate buffer layer and a portion of the gate buffer layer is exposed. Next, a doping process is performed to form the lightly doped drain region in the polysilicon layer underneath the exposed portion of the gate buffer layer. Thus, a low temperature polysilicon thin film transistor is formed via a simplified process and the overall fabrication cost can be reduced and the production efficiency can be substantially improved.

### BACKGROUND OF THE INVENTION

1. Field of the Invention

The present invention relates to a semiconductor device and a method of fabricating thereof. More particularly, the present invention relates to a low temperature polysilicon thin film transistor and a method of fabricating lightly doped drain thereof.

2. Description of Related Art

In the early stage, a polysilicon thin film transistors is formed by a solid phase crystallization process. However, since this process temperature is about 1000° C., a quartz substrate with a high melting point has to be used. Since the quartz substrate is more expansive than the glass substrate and the substrate size is restricted, the panel size is only about two to three inches. Therefore, only small panels are developed in past years. With the continuous advancement of the laser technology in recent years, an excimer laser annealing (ELA) process is developed. In a typical ELA process, a laser beam is irradiated to an amorphous silicon thin film, and the amorphous silicon thin film is melted and then recrystallized to from a polysilicon thin film. The whole ELA process can be completed at a temperature less than 600° C. The ploysilicon thin film transistors made by the aforementioned method is also known as low temperature polysilicon (LTPS) thin film transistors.

FIG. 1 is a schematic cross-sectional view showing a low temperature polysilicon thin film transistor according to the prior art. Referring to FIG. 1, a buffer layer 102 is arranged over the substrate 100 and a polysilicon layer 110 is disposed over the buffer layer 102. The polysilicon layer 110 includes a source region 112 and a drain region 114, which are formed by a doping process, and a channel region 116 is formed between the source region 112 and the drain region 114.

Still referring to FIG. 1, a gate insulation layer 120 covers the polysilicon layer 102 and the buffer layer 102, and a gate 130 is correspondingly arranged over the gate insulation layer 120 covering the channel region 116. A dielectric layer 140 is disposed over the gate 130 and the gate insulation layer 120, and source contact openings 112a and 114a are formed therein. A source metal layer 152 and the drain metal layer 154 are disposed over a dielectric layer 140 and through the dielectric layer 140 via source contact openings 112a and 114a to electrically connect with the source region 112 and drain region 114.

In order to avoid short channel effect, a lightly doped drain region 118 is formed between the channel region 116 and the source/drain regions 112 and 114. In the process of the prior art, the lightly doped drain region 118 and the source/drain regions 112 and 114, which have different doping concentration, are formed by two mask processes and at least two doping processes. However, it is difficult to align the patterns of the photomask for forming the lightly doped drain region 118. Even if the lightly doped drain region 118 is formed by a self-align doping process, the process is complicated.

### SUMMARY OF THE INVENTION

The present invention is directed to a low temperature polysilicon thin film transistor and a method of fabricating the same capable of simplifying the processes and improving the production efficiency.

The present invention is also directed to a method of fabricating a lightly doped drain to simplify the processes and improve the production efficiency.

The present invention is further directed to a low temperature polysilicon thin film transistor having a lightly doped drain with gradient dopant concentration.

The present invention is further directed to a method of fabricating a lightly doped drain having gradient dopant concentration.

According to one embodiment of the present invention, the low temperature polysilicon thin film transistor comprises a substrate, a polysilicon layer, a gate insulation layer, a gate buffer layer, a gate, a dielectric layer, a source metal layer and a drain metal layer. The polysilicon layer is disposed over the substrate. A lightly doped drain is formed in thepolysilicon layer and a channel region is formed inside the lightly doped drain region and a source/drain region is formed outside of the lightly doped drain region. The gate insulation layer is disposed over the substrate covering the polysilicon layer. The gate buffer layer is arranged over the gate insulation layer covering the channel region and the lightly doped drain. The dielectric layer is arranged over the gate insulation layer and the gate. The drain metal layer is disposed over the dielectric layer and through the dielectric layer and the gate insulation layer to electrically connect with the drain region. The source metal layer is disposed over the dielectric layer and through the dielectric layer and the gate insulation layer to electrically connect with the source region.

In the low temperature polysilicon thin film transistor according to an embodiment of the present invention, the material constituting the gate can be a metal and the material constituting the gate buffer layer can be a metal oxide, a metal nitride, a metal carbide or a metal containing dopant. The amount of oxygen, nitrogen, carbon or dopant of the gate buffer layer is decreased when the distance from the gate buffer layer to the gate insulation layer is increased.

In the low temperature polysilicon thin film transistor according to an embodiment of the present invention, the portion of the lightly doped drain nearer to the source/drain region has higher dopant concentration relative to elsewhere within the lightly doped drain. Furthermore, a structure of the gate buffer layer is tapered or ladder-shape.

According to the another embodiment of the present invention, a method of fabricating a lightly doped drain region is provided. First, a polysilicon layer is formed over a substrate, and then a gate insulation layer is formed over the polysilicon layer. A gate buffer layer and a gate are formed over the gate insulation layer, wherein the gate is formed over the gate buffer layer and a portion of the gate buffer layer is exposed. Next, a doping process is performed to form the lightly doped drain region in the polysilicon layer, wherein the lightly doped drain region is correspondingly disposed under the exposed portion of the gate buffer layer.

According to an embodiment of the present invention, the gate buffer layer and the gate can be formed by sequentially depositing a gate buffer material layer and a gate material layer over the gate insulation layer. Thereafter, the gate buffer material layer and the gate material layer are etched by an etching solution to form the gate buffer layer and the gate, simultaneously. The etching solution is selected such that an etching rate of the gate material is larger than that of the gate buffer layer. The gate buffer material layer and a gate material layer can be formed by a sputtering process. Specifically, the gate buffer material layer is formed by a sputtering process containing a reactive gas, wherein the reactive gas can be a gas containing oxygen, nitrogen, carbon or dopant. Further, the flow rate of the reactive gas is decreased with time.

As described above, the lightly doped drain under the exposed portions of the gate buffer layer, wherein the gate buffer layer is adapted for providing ion shielding effect during the doping process. The gate buffer layer and the gate are formed by using one mask process. Further, the lightly doped drain region and the source/drain regions can be formed simultaneously by one doping process. Therefore, the cost of fabricating the low temperature polysilicon thin fin transistor and the lightly doped drain according to an embodiment of the present invention can be effectively reduced, and also the fabrication process can be effectively simplified and thereby improving the production efficiency.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1 is a schematic cross-sectional view showing a conventional low temperature polysilicon thin film transistor.

FIG. 2A to 2I are a schematic cross-sectional views showing the progressive steps in the method of fabricating a low temperature polysilicon thin fin transistor according to the first embodiment of the present invention.

FIG. 3 is a schematic cross-sectional views showing a low temperature polysilicon thin film transistor according the second embodiment of the present invention.

FIG. 4 is a schematic cross-sectional views showing a low temperature polysilicon thin film transistor according the third embodiment of the present invention.

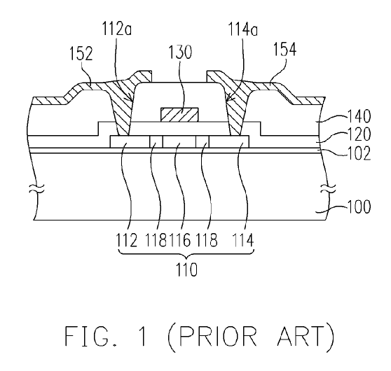

### DESCRIPTION OF THE EMBODIMENTS

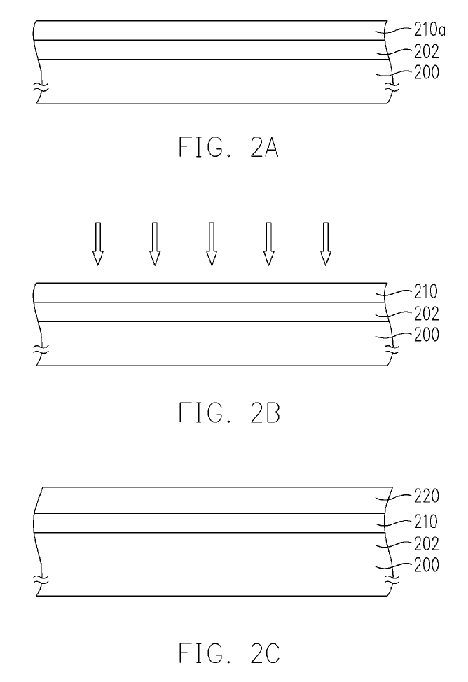

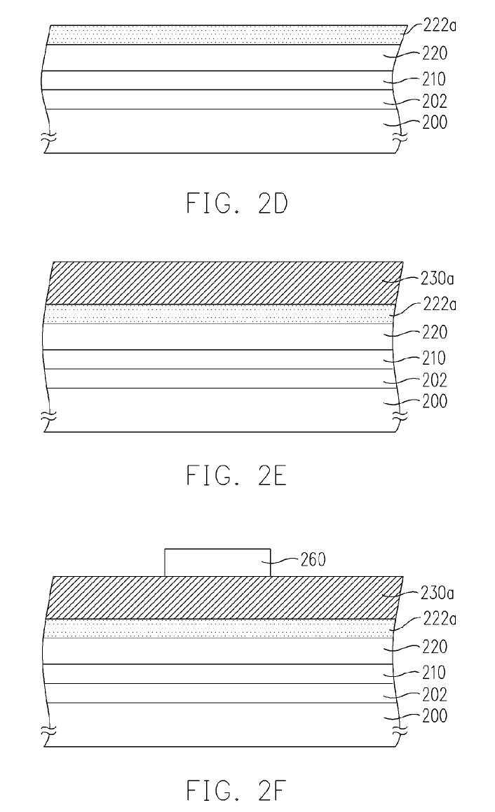

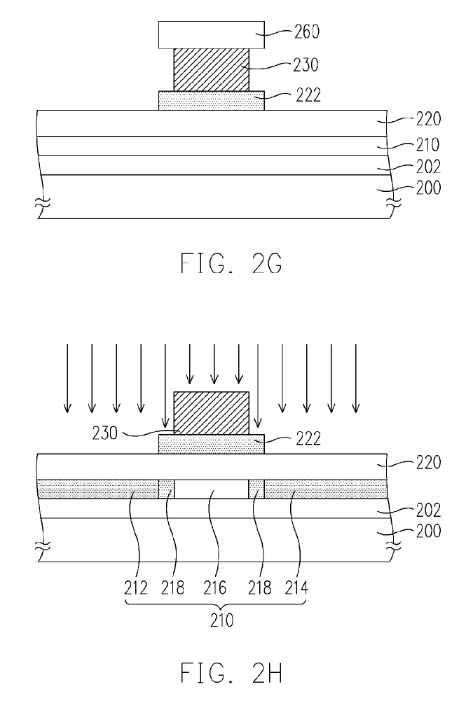

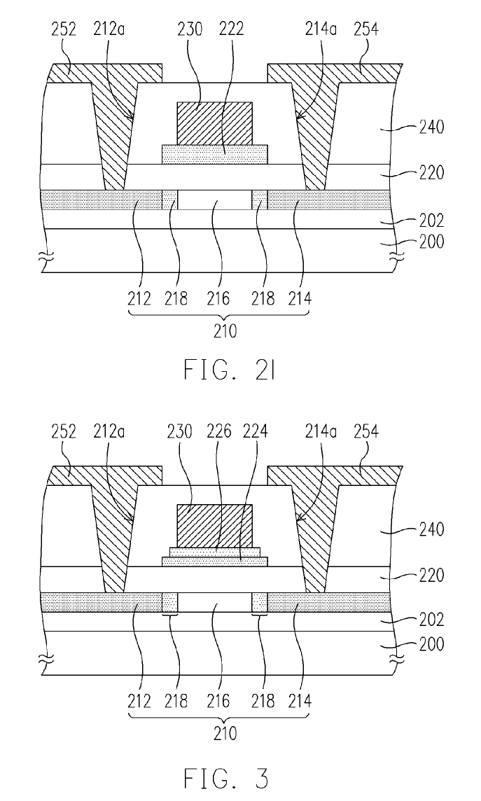

FIG. 2A to 2I are a schematic cross-sectional views showing the progressive steps in the method of fabricating a low temperature polysilicon thin film transistor according to a first embodiment of the present invention.

Referring to FIG. 2A, a buffer layer 202 is formed over a substrate 200 and then an amorphous layer 210a is formed over the buffer layer 202. The material constituting the substrate 200 is glass, while the buffer layer 202 is made of silicon dioxide, for example. The buffer layer 202 is used for increasing the adhesion strength between the substrate 200 and a subsequently formed polysilicon layer 210 (shown in FIG. 2B) and preventing the metal ions such as sodium ion in the substrate 200 from contaminating the polysilicon layer 210.

Next, referring to FIG. 2B, a dehydrogenation process and a laser anneal process such as an excimer laser anneal are performed so that the amorphous layer 210a is recrystallized to form a polysilicon layer 210.

Thereafter, referring to FIG. 2C, a gate insulation layer 220 is formed over the polysilicon layer 210. The material constituting the gate insulation layer 220 is silicon nitride or silicon oxy-nitride formed by a chemical vapor deposition process, for example.

Referring to FIG. 2D, a gate buffer layer 222a is formed over the gate insulation layer 220. The material gate buffer layer 222a constituting the gate buffer layer comprises a metallic compound. In one embodiment, the metallic compound is selected from a group consisting of a metal oxide, a metal nitride and a metal carbide. The metallic compound is formed by a sputtering process. The sputtering process uses a target and contains a reactive gas. The target used in the sputtering process includes metals selected from a group consisting of Cr, Al, Cu and Mo, for example. The metal species bombarded from the target react with the reactive gas are used to form the gate buffer layer 220. The reactive gas is selected from a group consisting of an oxygen containing gas, a nitrogen containing gas, a carbon containing gas and a dopant containing gas, for example.

Referring to FIG. 2E, a gate material layer 230a is formed over the gate buffer layer 222a. The material constituting the gate material layer 230a comprises metal. The metal is selected from a group consisting of Cr, Al, Cu and Mo and can be formed by sputtering. Therefore, after forming the gate buffer layer 222a, the sputtering process can be continued using the target but without the reactive gas to form a gate material layer 230a on the gate buffer layer 222a. The metal species bombarded from the target are deposited directly on the gate buffer layer 222a to form the gate material layer 230a. Hence, the etching rate of the gate buffer material layer 222a is different from that of the gate material layer 230a.

Referring to FIG. 2F, a patterned photoresist layer 260 is formed over the gate material layer 230a via spin-coating photoresist, exposure and development processes.

Referring to FIG. 2G, the gate material layer 230a and the gate buffer material layer 222a are etched using the patterned photoresist layer 260 as an etching mask to form a gate 230 and a gate buffer material layer 222. An etching solution used in the etching process is selected such that an etching rate of the gate material layer 230a is larger than that of the gate buffer material layer 222a. Therefore, the gate material layer 230a exposed by the patterned photoresist layer 260 is removed first. Thereafter, the gate buffer material layer 222a exposed by the patterned photoresist layer 260 is etched to form the gate buffer layer 222. In the meantime, the gate material layer 230a under the patterned photoresist layer 260 is over-etched to form the gate 230, thus, the edge of the gate buffer layer 222 is exposed.

Referring to FIG. 2H, the patterned photoresist layer 260 is removed. Thereafter, a doping process is performed to form source region 212, drain region 214 and a lightly doped drain region 218 using the gate 230 as a mask, and at the same time a channel region 216 is defined between the source region 212 and the drain region 214 in the polysilicon layer 210. The dopant used in the doping process is an n-typed dopant or p-type dopant. The source region 212 and the drain region 214 are correspondingly disposed under the gate insulation layer 220 exposed by the gate buffer layer 222. The lightly doped drain region 218 is correspondingly disposed under the exposed portion of the gate buffer layer 222. The dopant concentration of the lightly doped drain 218 is lighter than that of the source region 212 and the drain region 214 because of ion shielding effect provided by of the exposed portion of the gate buffer layer 222.

Referring to FIG. 2I, a dielectric layer 240 is formed over the gate insulation layer 220, and then a source contact opening 212a and a drain contact opening 214a are formed in the dielectric layer 240 to expose a portion of source region 212 and the drain region 214, respectively. Thereafter, a source metal layer 252 and a drain metal layer 254 are formed over the dielectric layer 240 filling the source contact opening 212a and the drain contact opening 214a electrically connecting with the source region 212 and the drain region 214, respectively.

As described above, the low temperature polysilicon thin film transistor comprises a gate buffer layer between the gate and the gate insulation layer. During the doping process, the exposed portion of the gate buffer layer can shield a portion of ions to form the lightly doped drain under the exposed portion of the gate buffer layer. Therefore, the dopant concentration of the lightly doped drain is lighter than that of the source region and the drain region. Moreover, the gate buffer layer can be formed by a sputtering process using a reactive gas and an etching process having an etching selectivity between the gate material layer and the gate buffer layer.

According to another embodiment of the present invention, the flow rate of the reactive gas can be altered when the portion of the gate buffer layer to be formed nearby the gate insulation layer has lower amount of metal.

FIG. 3 is a schematic cross-sectional views showing a low temperature polysilicon thin film transistor according a second embodiment of the present invention. Referring to FIG. 3, a first gate buffer layer 224 and a second buffer layer 226 substitute the gate buffer layer 222 shown in FIG. 2I. The content of oxygen, nitrogen, carbon or dopant in the first gate buffer layer 224, which is located nearby the gate insulation layer 220, is larger than that of the second gate buffer layer 226, which is located nearby the gate 230. Further, the second gate buffer layer 226 exposes a portion of the first buffer layer 224. Hence, the ion shielding effect of the first buffer layer 224 and that of the second buffer layer 226 are different. Accordingly, the lightly doped drain 218 formed via a doping process has two different dopant concentrations. The first gate buffer layer 224 and the second gate buffer layer 226 can be formed by a sputtering process using two flow rates of the reactive gas to form a first gate buffer material layer and a second buffer material layer. The content of oxygen, nitrogen, carbon or dopant in the first gate buffer material layer larger than that of the second buffer material layer, for example. Thereafter, the first gate buffer material layer and the second buffer material layer are patterned by an etching process to form the first gate buffer layer 224 and the second gate buffer layer 226. The etching rate of the first gate buffer material layer is lower than the second gate buffer material layer. Therefore, the width of the first gate buffer layer 224 is larger than the width of the second gate buffer layer 226 and edge portions of the second buffer layer 226 and the first gate buffer layer 224 are exposed. Furthermore, in the lightly drain region 218 which is formed in the doping process, the dopant concentration of the region near the channel region 216 is lighter than that of the region near the source region 212 and the drain region 214.

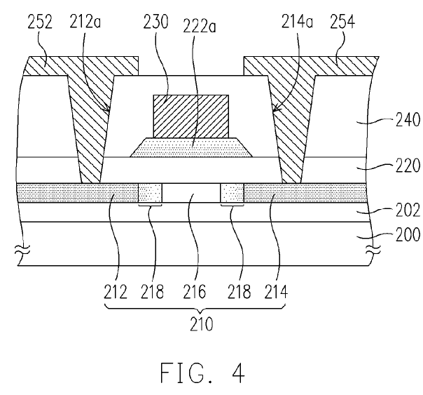

FIG. 4 is a schematic cross-sectional view showing a low temperature polysilicon thin film transistor according a third embodiment of the present invention. Referring to FIG. 4, the structure of the thin film transistor comprises a tapered gate buffer layer 222a instead of the gate buffer layer 222 shown in FIG. 2I. The content of oxygen, nitrogen, carbon or dopant in the tapered gate buffer layer 222a decreases with the increasing height of the tapered gate buffer layer 222a and thus the tapered gate buffer layer 222a with a gradient oxygen, nitrogen, carbon or dopant content therein. The tapered gate buffer layer 222a can be formed by a sputtering process using a plurality of flow rates of the reactive gas containing oxygen, for example, wherein the flow rates of the reactive gas is decreased with time, to form a gradient gate buffer material layer with a gradient oxygen, nitrogen, carbon or dopant content therein. Thereafter, the gradient gate buffer material layer is etched to form the gate buffer layer 222a. The structure of gate buffer layer 222a is tapered because the gate buffer material layer has gradient oxygen concentration. Hence, the exposed portion of the tapered gate buffer layer 222a near to the gate 230 has larger ion shielding effect. Therefore, after the doping process, a lightly doped drain 218 with a gradient dopant concentration is formed, wherein the portion of the lightly doped drain 218 nearer to the source/drain region 212 and 214 has higher dopant concentration.

In other words, an etching property and structure of the gate buffer layer can be varied by controlling the flow rates of the reactive gas during the deposition process. Accordingly, a ladder-shape or a taper-shape gate buffer layer can be formed by controlling the flow rates of the reactive gas during the deposition process. It should be noted that the gate buffer layer mentioned above is used for describing the present invention, and therefore the gate buffer layer should not used to limit the scope of the present invention. One skilled in the art will understand that by using desired reactive gas and by varying the flow rates of the reactive gas during the deposition process a lightly doped drain with a desired profile can be obtained.

To sum up, the lightly doped drain is formed by using a gate buffer layer having ion shielding effect during the doping process. The gate buffer layer and the gate are formed using a single mask process. Comparing with the prior art, the present invention is capable of reducing one mask process and the problem of the misalignment masks can be effectively overcome. Further, the lightly doped drain and the source/drain region can be formed simultaneously in a single doping process. Therefore, the overall fabrication of the low temperature polysilicon thin film transistor and the lightly doped drain can be effectively reduced, and the processes can be significantly simplified and thus the production efficiency can be effectively improved.

It will be apparent to those skilled in the art that various modifications and variations can be made to the structure of the present invention without deportioning from the scope or spirit of the invention. In view of the foregoing, it is intended that the present invention covers modifications and variations of this invention provided they fall within the scope of the following claims and their equivalents.

1. The low temperature polysilicon thin film transistor, comprising:
a substrate;
a polysilicon layer, disposed over the substrate, and the polysilicon layer comprising a lightly doped drain, a channel region inside the lightly doped drain region and a source/drain region outside the lightly doped drain region;
a gate insulation layer, disposed over the substrate covering the polysilicon layer;
a gate buffer layer, arranged over the gate insulation layer covering the channel region and the lightly doped drain;
a gate, disposed over the gate buffer layer covering the channel region, wherein the gate buffer layer is disposed between the gate and the gate insulation layer;
a dielectric layer, arranged over the gate insulation layer covering the gate;
a drain metal layer, disposed over the dielectric layer and through the dielectric layer and the gate insulation layer to electrically connect with the drain region; and
a source metal layer, disposed over the dielectric layer and through the dielectric layer and the gate insulation layer to electrically connect with the source region.

2. The low temperature polysilicon thin film transistor of claim 1, wherein a material constituting the gate comprises a metal.

3. The low temperature polysilicon thin film transistor of claim 2, wherein a material constituting the gate buffer layer comprises a metallic compound.

4. The low temperature polysilicon thin film transistor of claim 3, wherein the metallic compound is selected from a group consisting of a metal oxide, a metal nitride and a metal carbide.

5. The low temperature polysilicon thin film transistor of claim 3, wherein the portion of the gate buffer layer nearer to the gate insulation layer has lower amount of metal.

6. The low temperature polysilicon thin fin transistor of claim 1, wherein a material constituting the gate buffer layer comprises a dopant containing material.

7. The low temperature polysilicon thin fin transistor of claim 6, wherein the portion of the gate buffer layer nearer to the gate insulation layer has more amount of dopant.

8. The low temperature polysilicon thin fin transistor of claim 1, wherein a portion of the lightly doped drain nearer to the source/drain region has a higher dopant concentration.

9. The low temperature polysilicon thin film transistor of claim 1, wherein a structure of the gate buffer layer is ladder-shape.

10. The low temperature polysilicon thin film transistor of claim 1, wherein a structure of the gate buffer layer is taper-shape.

11. The low temperature polysilicon thin film transistor of claim 1, further comprising a buffer layer arranged between the substrate and the polysilicon layer.

12. The method of fabricating a lightly doped drain region, comprising:
forming a polysilicon layer over a substrate;
forming a gate insulation layer over the polysilicon layer;
sequentially forming a gate buffer layer over the gate insulation layer and a gate over the gate buffer layer so that the gate buffer layer is formed between the gate and the gate insulation layer, wherein an edge portion of the gate buffer layer is exposed; and
performing a doping process to form a lightly doped drain region in the polysilicon layer underneath the exposed portion of the gate buffer layer.

13. The method of fabricating a lightly doped drain region of claim 12, wherein the steps of forming the gate buffer layer and the gate comprises;
forming a gate buffer material layer over the gate insulation layer and forming a gate material layer over the gate buffer layer; and
patterning the gate material layer and the gate buffer material layer to form the gate and the gate buffer layer using a photolithography process and an etching process, wherein an etching rate of the gate material is larger than that of the gate buffer material.

14. The method of fabricating a lightly doped drain region of claim 13, wherein the gate material is formed by a sputtering process and the gate buffer material layer is formed by a sputtering process containing a reactive gas.

15. The method of fabricating a lightly doped drain region of claim 14, wherein the reactive gas is selected from a group consisting of an oxygen containing gas, a nitrogen containing gas and a carbon containing gas.

16. The method of fabricating a lightly doped drain region of claim 14, wherein the reactive gas comprises a dopant containing gas.

17. The method of fabricating a lightly doped drain region of claim 14, wherein an amount of the reactive gas is decreased with time during the sputtering process.

18. The method of fabricating a lightly doped drain region of claim 12, further comprises a step of forming a buffer layer over the substrate before the step of forming the polysilicon layer over the substrate.
